(19) United States
(12) Patent Application Publication
(10) Pub. No.: US 2009/0224250 A1
(43) Pub. Date: Sep. 10, 2009

(54) Top Gate Thin Film Transistor with Enhanced Off Current Suppression

(76) Inventors: Hidayat Kisdarjono, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/045,286

(22) Filed: Mar. 10, 2008

(51) Int. Cl. H01L 29/786; H01L 21/335

(52) U.S. Cl. 257/66; 438/151; 257/411; 257/E21.535; 257/E29.299

(57) ABSTRACT

A bottom-contacted top gate thin film transistor (TFT) with enhanced off current suppression is provided, along with an associated fabrication method. The method provided a substrate. Source and drain regions are formed overlying the substrate, each having a channel interface top surface. A channel is interposed between the source and drain, with contact regions immediately overlying the source/drain (S/D) interface top surfaces. A first dielectric layer is conformally deposited. Then, a second dielectric layer is formed overlying the S/D interface top surfaces, with an opening exposing a portion of the first dielectric overlying the channel. A gate is formed overlying the second dielectric layer and the exposed portion of the first dielectric layer.

### BACKGROUND OF THE INVENTION

1. Field of the Invention

This invention generally relates to integrated circuit (IC) fabrication and, more particularly, to a gate dielectric structure that permits enhanced off current suppression in a top gate thin-film transistor (TFT).

2. Description of the Related Art

FIGS. 1A and 1B are, respectively, partial cross-sectional views of bottom gate and top gate TFT devices made using an amorphous silicon (Si) active layer (prior art). For ease of fabrication using well-established process flows, the channel is formed from a thin-film material that is interposed between the source and drain, while overlapping the regions (contact regions) of the source and drain. Such a structure is optimal for amorphous Si (a-Si) active layer because the gate/contact overlap ensures low contact resistance without causing high off current.

To economically fabricate higher quality consumer devices such a liquid crystal display (LCD) televisions, so-called mid-mobility TFTs may be fabricated over glass panel substrates using mid-mobility materials (e.g. microcrystalline silicon (μc-Si)) as the active layer, in place of more conventional materials such as a-Si. In addition to the higher effective mobility due to better quality active layer, these TFT's are required to have a similar or lower level of off-current. Except for this active layer deposition step, it is desirable that the devices are fabricated using conventional TFT process technology. The use of these mid-mobility devices could provide a technical path to the integration of a variety of circuits and address the so-called system-on-panel concept.

However, the above-described channel contact structure is not necessarily optimal for use with mid-mobility active layers made from μc-Si. When μc-Si replaces a-Si as active layer in the conventional structure, operation in the off-state subjects the μc-Si active layer to very large field. The smaller energy gap, higher mobility, and large defect density in the active film results in off current levels that are much higher than if a-Si is used. Alternately stated, the simplicity of conventional structure and processes puts constraints on the off-current parameter, because of the large overlap between gate and contact regions.

Thus, if a mid-mobility material such as μc-Si is to be used in place of a-Si, an alternative structure is needed to address the issue of high off-state current due to field-enhanced carrier generation. Without the capability of suppressing the off-current, an overall increase in the current ON/OFF ratio cannot be realized.

It would be advantageous if a TFT structure could be devised that minimizes the electric field influencing the active layer at the contact region. It would be advantageous if the improved TFT had a lower off-current than a conventional top-gate TFT.

### SUMMARY OF THE INVENTION

To address the above-mentioned problems, a structure is presented that maintains good contact between the channel (e.g., μc-Si) and the source/drain (S/D) regions (e.g. n+ Si) of the contact layer, while reducing the field at contact/gate overlap area. The electric field is reduced at the contact region where dielectric is made thicker, thereby suppressing carrier generation and off-current. The structure is realized without resorting to high resolution photolithography.

Accordingly, a method is provided for forming a bottom-contacted top gate thin film transistor (TFT) with enhanced off current suppression. A substrate is provided. Source and drain regions are formed overlying the substrate, each having a channel interface top surface. A channel is interposed between the source and drain, with contact regions immediately overlying the source/drain (S/D) interface top surfaces. A first dielectric layer is conformally deposited. Then, a second dielectric layer is formed overlying the S/D interface top surfaces, with an opening exposing a portion of the first dielectric overlying the channel. A gate is formed overlying the second dielectric layer and the exposed portion of the first dielectric layer.

In one aspect, the formation of the S/D regions includes the step forming a drain region having a channel interface edge. Then, the formation of the second dielectric opening includes the step of forming a second dielectric opening edge overlying the channel, in the range of 0 to 7500 Å from the drain channel interface edge.

Additional details of the above-described method and a bottom-contacted top gate TFT with enhanced off current suppression are provided below.

### BRIEF DESCRIPTION OF THE DRAWINGS

FIGS. 1A and 1B are, respectively, partial cross-sectional views of bottom gate and top gate TFT devices made using an amorphous silicon (Si) active layer (prior art).

FIG. 2 is a partial cross-sectional view of a bottom-contacted top gate thin film transistor (TFT) with enhanced off current suppression.

FIG. 3 is a partial cross-sectional view of a variation of the top gate TFT of FIG. 2.

FIG. 4 is a graph comparing the IDVG curves for the device of FIG. 1B and the device of FIG. 3.

FIG. 5 is a partial cross-sectional view detailing an aspect of the top gate TFT of FIG. 3.

FIG. 6 is a graph depicting the drain current as a function of the A and B rectangular area parameters.

FIGS. 7A through 7G depict steps in the fabrication of a top gate TFT with enhanced off-current suppression.

FIG. 8 is a flowchart illustrating a method for forming a bottom-contacted top gate TFT with enhanced off current suppression.

### DETAILED DESCRIPTION

FIG. 2 is a partial cross-sectional view of a bottom-contacted top gate thin film transistor (TFT) with enhanced off current suppression. The TFT 200 comprises a substrate 202, which may be a material such as metal foil, Si, glass, plastic, or quartz. However, other unnamed substrate materials may also be used that are well known in the art. A source region 204 and a drain region 206 overlie the substrate 202, each having a channel interface top surface 208a and 208b, respectively. A channel 210 interposed between the source 204 and drain 206, with contact regions 212a and 212b, respectively, immediately overlying the source/drain (S/D) interface top surfaces 208a and 208b.

A first dielectric layer 214 overlies the channel 210, source 204, and drain 206. A second dielectric layer 216 overlies the S/D interface top surfaces 208, with an opening 217 exposing a portion 218 of the first dielectric 214 overlying the channel 210. A gate 220 overlies the second dielectric layer 216 and the exposed portion 218 of the first dielectric layer 214. In one aspect not shown, an etch stop dielectric layer may intervene between the first dielectric layer 214 and the second dielectric layer 216, see FIG. 9G. In one aspect, the first dielectric layer 214 is silicon dioxide having a thickness 232 of about 1000 Å, the second dielectric layer 216 is silicon dioxide having a thickness 234 of 2000 Å.

The first dielectric layer 214 and second dielectric layer 216 are each a material such as silicon nitride, silicon dioxide, or organic dielectrics. However, other dielectrics may also be used that are known in the art. In one aspect, the first and second dielectric layers are different materials. If an etch stop is used, it may be a different material than either the first or second dielectrics. In another aspect, the first dielectric layer 214 has an interfacial defect density adjacent the channel 210 not exceeding 1×10¹² (cm² eV)⁻¹.

The source 204 and drain 206 regions may be a material such as amorphous Si (a-Si), microcrystalline Si, polysilicon, compound semiconductors (e.g., SiGe), metal oxide semiconductors (e.g., zinc oxide), doped microcrystalline Si, doped polysilicon, or doped a-Si. The channel 210 may be a material such as microcrystalline Si, polysilicon, a-Si, compound semiconductors, or metal oxide semiconductors. Note, the channel 210 may be made from a different material than the S/D regions 204/206.

In one aspect, the drain region 206 has a channel interface edge 222, source has a channel interface edge 230, and the second dielectric opening 217 includes an opening edge 224 overlying the channel 210. The opening edge 224 is in the range of 0 to 7500 Å from the drain channel interface edge 222. It should be understood that the above-mentioned range defines the difference between edges in the horizontal plane (left-to-right) as seen in cross-section, not the overall distance between the edges. The placement of opening edge 226 is not as critical as the placement of edge 224. Opening edge 226 may be over the channel (as is edge 224), over the contact region 212a, or even over the source 204. As shown, opening edge 226 is shown overlying the source 204. In other aspect, see FIG. 9G, there is no opening edge 226, as the second dielectric is formed only over the drain region of the TFT.

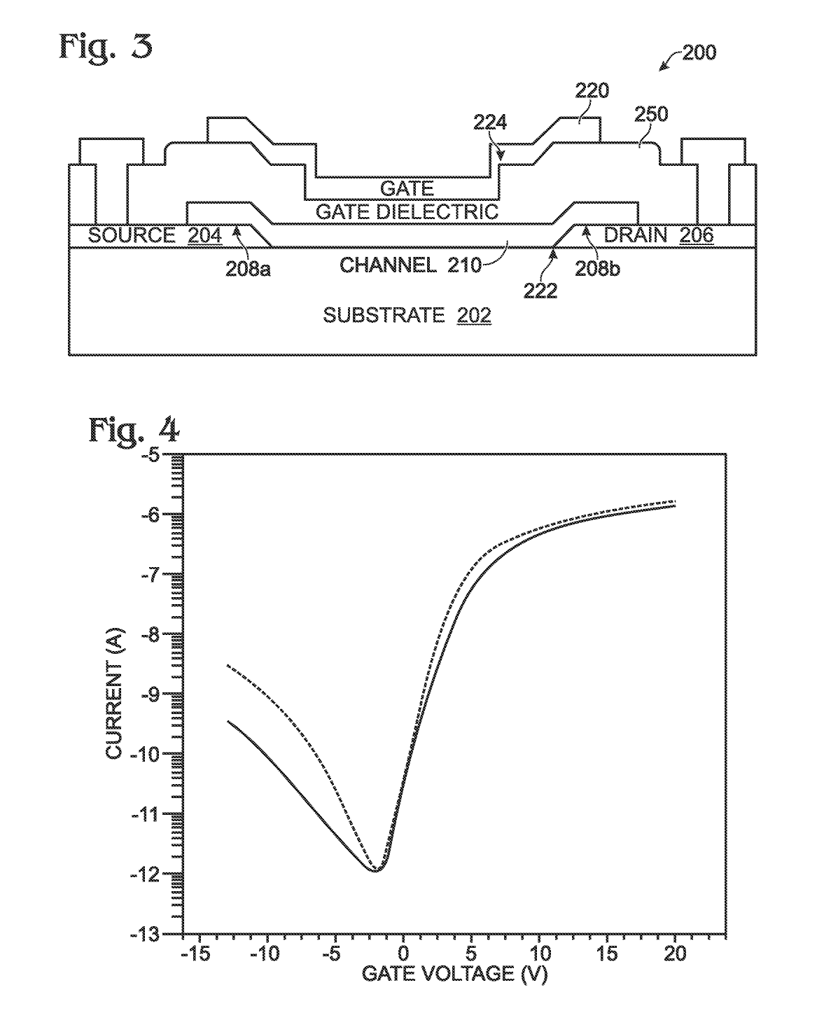

FIG. 3 is a partial cross-sectional view of a variation of the top gate TFT of FIG. 2. In this aspect, top gate TFT 200 may comprise a dielectric structure 250 overlying the channel, source, drain, and the S/D interface top surfaces 208a and 208b, with a step 224 overlying the channel 210. The step 224 is in the range of 0 to 7500 Å from the drain channel interface edge 222. In one aspect, dielectric structure 250 is made from a single dielectric layer that is selectively etched. Alternately, as shown in FIG. 2, the dielectric structure 250 includes the first dielectric layer 214 overlying the channel 210, source 204, and drain 206. The dielectric structure 250 also includes a second dielectric layer 216 overlying the S/D interface top surfaces 208a and 208b, where the step 224 is associated with opening 217, which exposes a portion 218 of the first dielectric overlying the channel 210.

### Functional Description

The TFT devices of FIGS. 2 and 3 can be made using processes compatible with the conventional TFT fabrication technology so that off-current improvements can be realized without a costly upgrade to existing production line.

To demonstrate the concept, device simulations were done using process/device simulation software with a physical model for μc-Si material. The simulations took into account band-to-band tunneling which had been identified as primary cause of off-current in the large field. At V_{DS}=2.5V and V_{GS}=−13V, the y-component of the electric field over the contact region in the device of FIG. 3 is reduced to about 70% of the field in the conventional device. The key difference is that in the invented device dielectric thickness is thicker at the contact region so that the field is minimized.

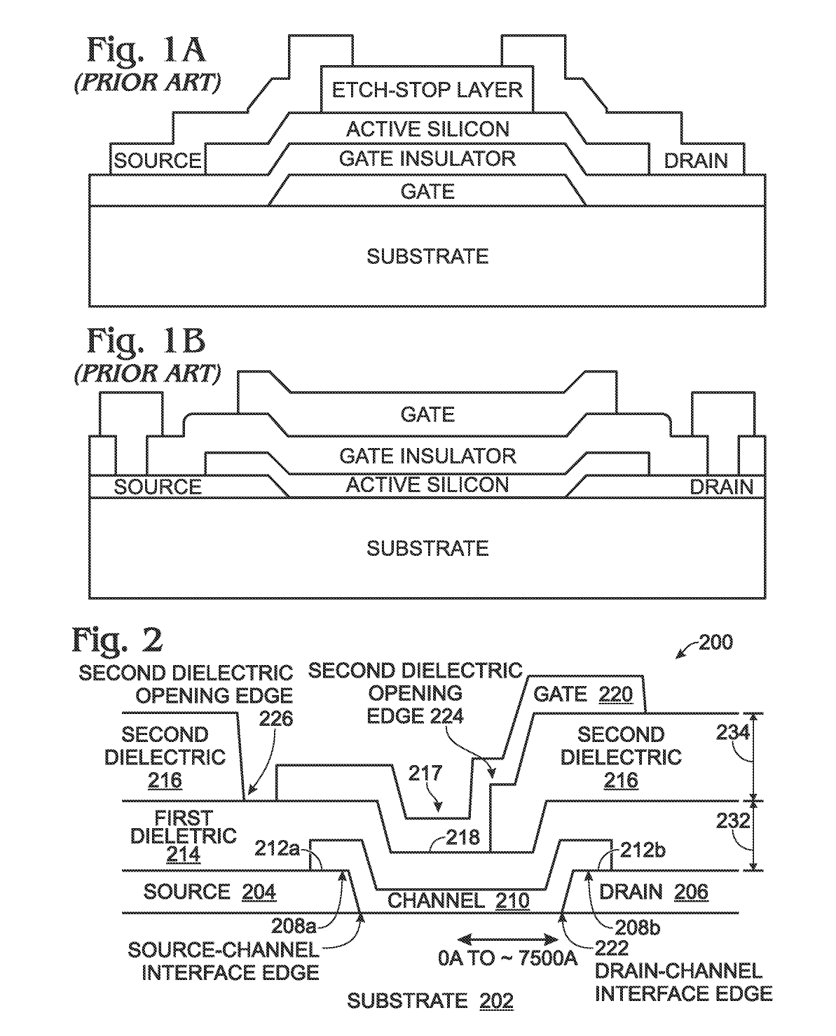

FIG. 4 is a graph comparing the IDVG curves for the device of FIG. 1B and the device of FIG. 3. At V_{GS}=13V and V_{GS}=20V, off-current is one order of magnitude lower for the device of FIG. 3 (the solid line), while on-currents are essentially the same. The invented device structure has little impact on on-current because the dielectric thickness over the channel remains the same.

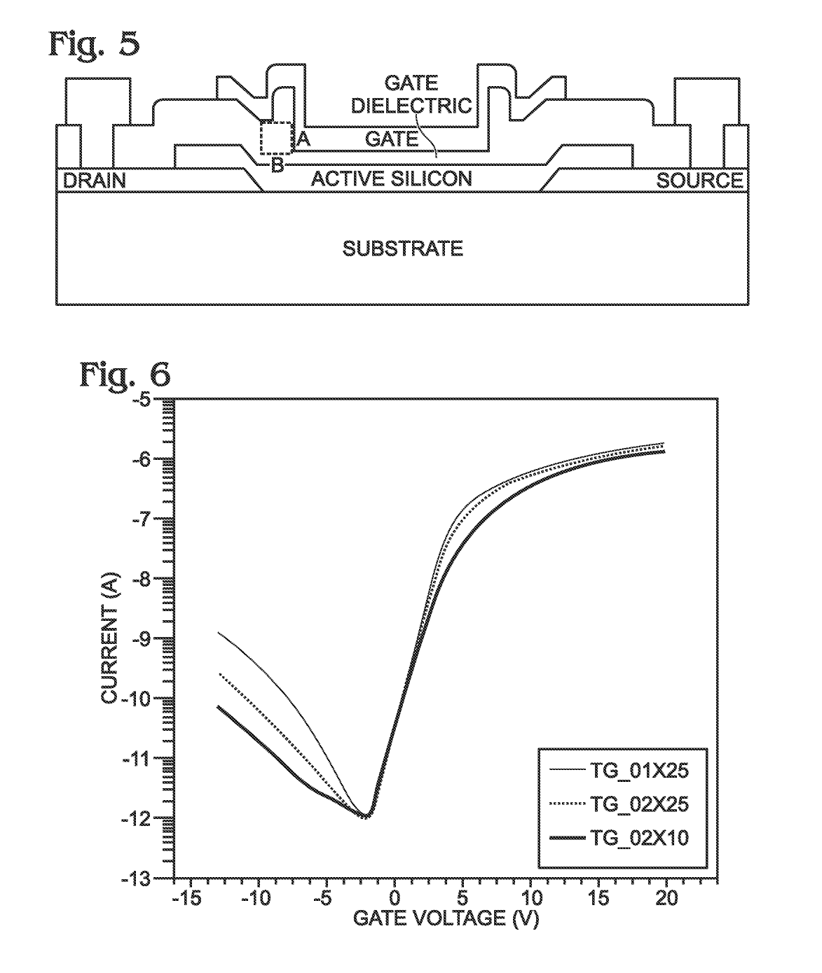

FIG. 5 is a partial cross-sectional view detailing an aspect of the top gate TFT of FIG. 3. The rectangular area overlying the drain-channel interface, bounded by the dashed lines, is important for device performance. Both the additional dielectric thickness over the contact region and the spacing between trench wall and edge of contact region increase the area of this rectangle. Increasing the rectangular area simultaneously reduces field and degradation of the on-current. Optimization of the device requires maximizing the rectangular area to reduce off-current, while adjusting the A and B parameters to maintain a large on-current.

FIG. 6 is a graph depicting the drain current as a function of the A and B rectangular area parameters.

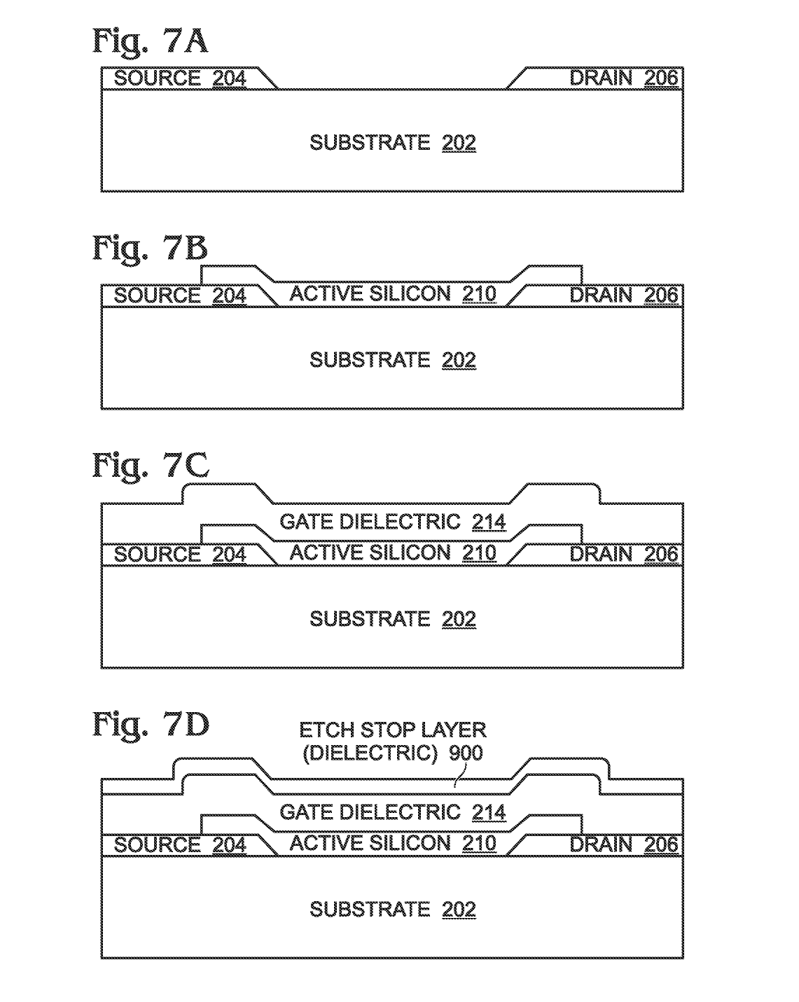

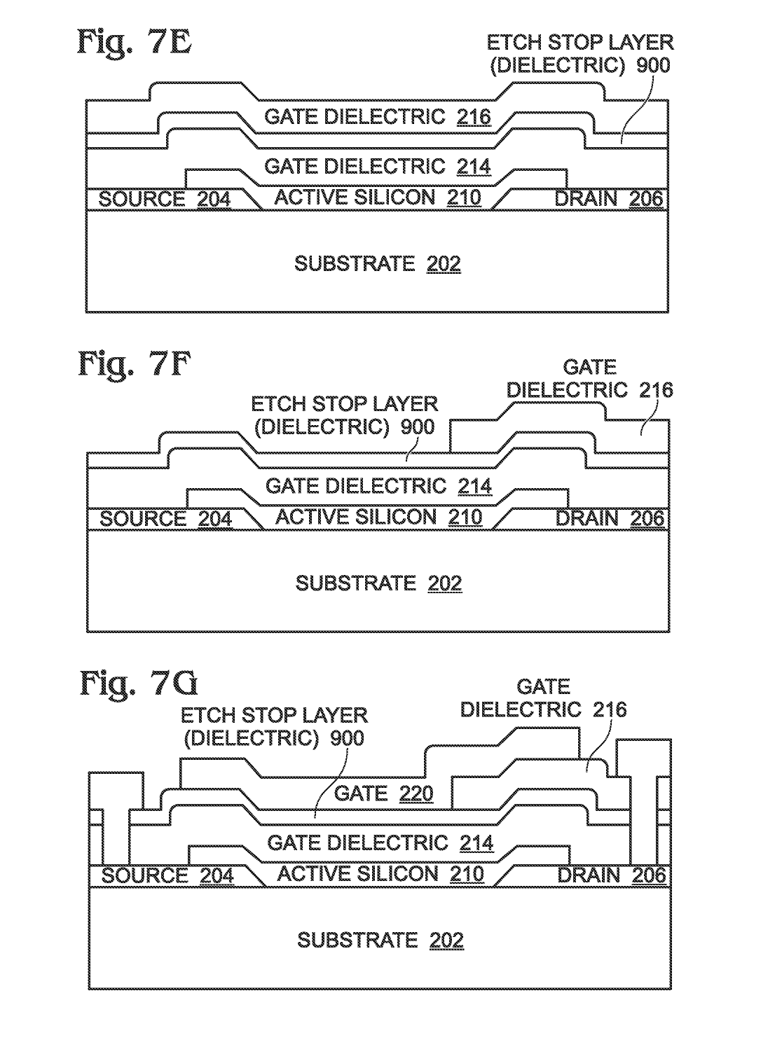

FIGS. 7A through 7G depict steps in the fabrication of a top gate TFT with enhanced off-current suppression. The depicted process uses an etch stop layer and forms an asymmetric gate. However, it should be understood that equivalent processes may be used that do not use an etch stop, or which form a symmetric gate. In FIG. 7a, the source and drain materials are deposited over a substrate 202 and patterned for contact. In FIG. 7B, a semiconductor layer is deposited for the channel 210 and patterned. In FIG. 7C, a bulk (first) dielectric is deposited. In FIG. 7D, an etch stop dielectric 900 is deposited. In FIG. 7E a second bulk dielectric 216 is deposited. In FIG. 7F the second dielectric 216 is patterned, stopping at the etch stop dielectric 900. In FIG. 7G contact vias/openings are etched to contact the S/D regions. Then, gate and metal interconnect layers are deposited and patterned.

To form source, drain and intrinsic channel regions from the same material, dopant atoms are used. The doping may be performed using either ion implant or diffusion. Both methods require high temperature annealing (700° C. and above). For the implant process, annealing is required to repair disorder caused by high energy atoms penetrating the doped material. For diffusion, annealing is required to diffuse the atoms through the doped material.

For most display applications, the overriding concern is cost. The substrate of choice is glass, which is sensitive to temperatures of greater than 500° C., or even plastic, which is sensitive to temperatures exceeding 300° C. Therefore, high temperature implantation and diffusion processes are not practical. In some aspects, a device can be fabricated from a single μc-Si layer and then implanted with dopant. Instead of thermal annealing, however, a laser annealing process may be used to concentrate thermal energy at the surface of the wafer.

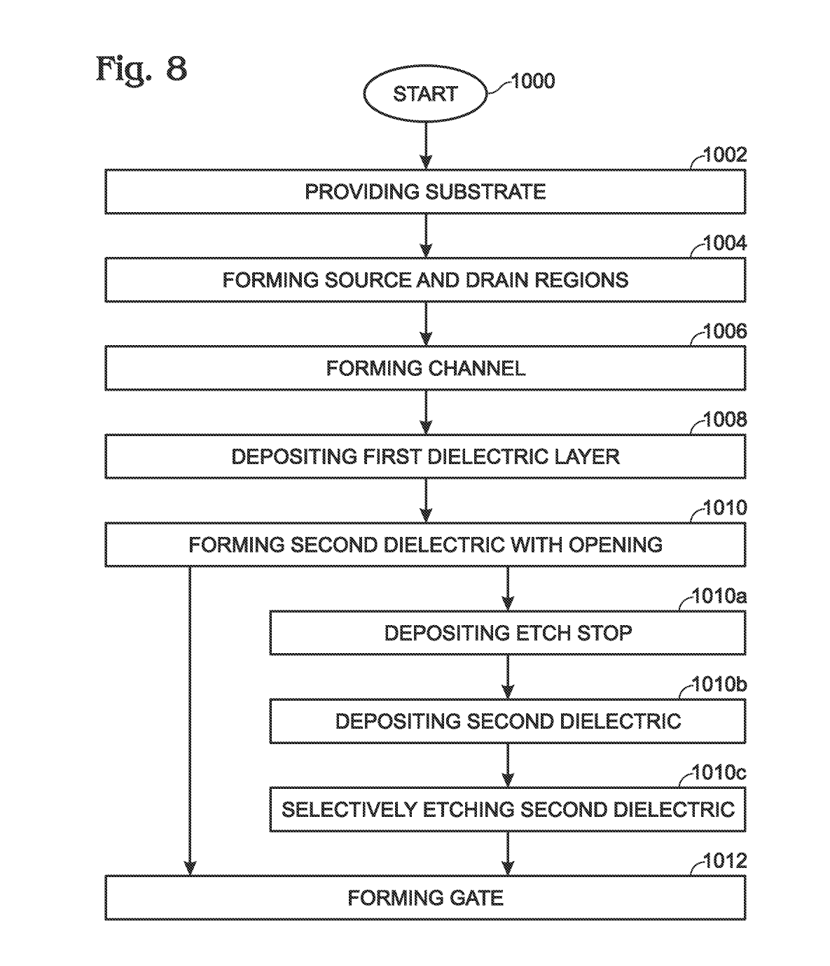

FIG. 8 is a flowchart illustrating a method for forming a bottom-contacted top gate TFT with enhanced off current suppression. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1000.

Step 1002 provides a substrate. For example, the substrate may be a material such as metal foil, Si, glass, plastic, or quartz. Step 1004 forms source and drain regions overlying the substrate, each having a channel interface top surface. Step 1006 forms a channel interposed between the source and drain, with contact regions immediately overlying the source/drain (S/D) interface top surfaces. Step 1008 conformally deposits a first dielectric layer. Step 1010 forms a second dielectric layer overlying the S/D interface top surfaces, with an opening exposing a portion of the first dielectric overlying the channel. Step 1012 forms a gate overlying the second dielectric layer and the exposed portion of the first dielectric layer.

In one aspect, forming the S/D regions in Step 1004 includes forming a drain region having a channel interface edge. Then, forming the second dielectric opening in Step 1010 includes forming a second dielectric opening edge overlying the channel, in the range of 0 to 7500 Å from the drain channel interface edge.

In one aspect, forming the second dielectric layer in Step 1010 includes substeps. Step 1010a conformally deposits an etch stop layer overlying the first dielectric layer. Step 1010b conformally deposits the second dielectric overlying the etch stop layer. Step 1010c selectively etches the second dielectric overlying the channel. The first dielectric layer, second dielectric layer, and etch stop may each be one of the following materials: silicon nitride, silicon dioxide, or organic dielectrics. Note: first and second dielectric layers may be different materials. If an etch stop is used, it may be a material different than the first and second dielectrics.

In one aspect, Step 1008 forms the first dielectric layer from silicon dioxide, 1000 Å thick, and Step 1010 forms the second dielectric layer from silicon dioxide, 2000 Å thick. In a different aspect, Step 1008 forms the first dielectric layer having an interfacial defect density adjacent the channel not exceeding 1×10¹² (cm² eV)⁻¹.

In one aspect, the source and drain regions are formed from a first material, while the channel is formed from a second material different than the first material. The first material may be microcrystalline Si, polysilicon, or a-Si. The channel (second) material may be microcrystalline Si, polysilicon, or a-Si. However, it is possible for the source, drain, and channel to be made from a common material such as a-Si, microcrystalline Si, polysilicon, compound semiconductors, or metal oxide semiconductors.

A top gate TFT and associated fabrication process, with enhanced off-current suppression has been provided. Examples of particular structures details and materials have been provided to illustrate the invention. However, the invention is not limited to merely these examples. Further, the same principles used to form the top gate TFT can be applied to the fabrication of bottom gate TFTs with enhanced off-current suppression. Other variations and embodiments of the invention will occur to those skilled in the art.

We claim:

1. A method for forming a bottom-contacted top gate thin film transistor (TFT) with enhanced off current suppression, the method comprising:
providing a substrate;
forming source and drain regions overlying the substrate, each having a channel interface top surface;
forming a channel interposed between the source and drain, with contact regions immediately overlying the source/drain (S/D) interface top surfaces;
conformally depositing a first dielectric layer;
forming a second dielectric layer overlying the S/D interface top surfaces, with an opening exposing a portion of the first dielectric overlying the channel; and,
forming a gate overlying the second dielectric layer and the exposed portion of the first dielectric layer.

2. The method of claim 1 wherein forming the second dielectric layer includes:
conformally depositing an etch stop layer overlying the first dielectric layer;
conformally depositing the second dielectric overlying the etch stop layer; and,
selectively etching the second dielectric overlying the channel.

3. The method of claim 2 wherein forming the first dielectric layer, second dielectric layer, and etch stop includes forming each layer from a material selected from a group consisting of silicon nitride, silicon dioxide, and organic dielectrics.

4. The method of claim 1 wherein forming the first and second dielectric layers includes forming the first and second dielectric layers from different materials.

5. The method of claim 1 wherein forming the first and second dielectric layers includes forming the first dielectric layer from silicon dioxide about 1000 Å thick and the second dielectric layer from silicon dioxide about 2000 Å thick.

6. The method of claim 1 wherein forming the first dielectric layer includes forming a first dielectric layer having an interfacial defect density adjacent the channel not exceeding 1×10¹² (cm² eV)⁻¹.

7. The method of claim 1 wherein forming the source and drain regions includes forming source and drain regions from a first material; and,
wherein forming the channel includes forming the channel from a second material different than the first material.

8. The method of claim 7 wherein forming separate source and drain regions from the first material includes the first material being doped materials selected from a group consisting of microcrystalline Si, polysilicon, and amorphous silicon (a-Si); and,
wherein forming the channel includes forming the channel from a material selected from a group consisting of microcrystalline Si, polysilicon, and a-Si.

9. The method of claim 1 wherein forming the source and drain regions includes forming the source and drain from a material selected from the group consisting of a-Si, microcrystalline Si, polysilicon, compound semiconductors, and metal oxide semiconductors; and,
wherein forming the channel region includes forming the channel region from a material selected from a group consisting of a-Si, microcrystalline Si, polysilicon, compound semiconductors, and metal oxide semiconductors.

10. The method of claim 1 wherein providing the substrate includes providing a substrate from a material selected from a group consisting of metal foil, Si, glass, plastic, and quartz.

11. The method of claim 1 wherein forming the S/D regions includes forming a drain region having a channel interface edge; and,
wherein forming the second dielectric opening includes forming a second dielectric opening edge overlying the channel, in the range of 0 to 7500 Å from the drain channel interface edge.

12. A bottom-contacted top gate thin film transistor (TFT) with enhanced off current suppression, the TFT comprising:
a substrate;
source and drain regions overlying the substrate, each having a channel interface top surface;
a channel interposed between the source and drain, with contact regions immediately overlying the source/drain (S/D) interface top surfaces;
a first dielectric layer overlying the channel, source, and drain;
a second dielectric layer overlying the S/D interface top surfaces, with an opening exposing a portion of the first dielectric overlying the channel; and,
a gate overlying the second dielectric layer and the exposed portion of the first dielectric layer.

13. The TFT of claim 12 wherein the first dielectric layer and second dielectric layer are each a material selected from a group consisting of silicon nitride, silicon dioxide, and organic dielectrics.

14. The TFT of claim 12 wherein the first and second dielectric layers are different materials.

15. The TFT of claim 12 wherein the first dielectric layer has an interfacial defect density adjacent the channel not exceeding 1×10¹² (cm² eV)⁻¹.

16. The TFT of claim 12 wherein the source and drain regions are a material selected from a group consisting of amorphous Si (a-Si), microcrystalline Si, polysilicon, compound semiconductors, metal oxide semiconductors, doped microcrystalline Si, doped polysilicon, and doped a-Si; and,
wherein the channel is a material selected from a group consisting of microcrystalline Si, polysilicon, a-Si, compound semiconductors, and metal oxide semiconductors.

17. The TFT of claim 12 wherein the substrate is a material selected from a group consisting of metal foil, Si, glass, plastic, and quartz.

18. The TFT of claim 12 wherein the drain region has a channel interface edge; and,
wherein the second dielectric opening includes an opening edge overlying the channel, in the range of 0 to 7500 Å from the drain channel interface edge.

19. A bottom-contacted top gate thin film transistor (TFT) with enhanced off current suppression, the TFT comprising:
a substrate;
source and drain regions overlying the substrate, each having a channel interface top surface;
a channel interposed between the source and drain, with contact regions immediately overlying the source/drain (S/D) interface top surfaces;
a dielectric structure overlying the channel, source, drain, and the S/D interface top surfaces, with a step overlying the channel, in the range of 0 to 7500 Å from a drain channel interface edge; and,
a gate overlying the dielectric structure.

20. The TFT of claim 19 wherein the dielectric structure includes:
a first dielectric layer overlying the channel, source, and drain; and,
a second dielectric layer overlying the S/D interface top surfaces, where the step is associated with an opening exposing a portion of the first dielectric overlying the channel.
